(19) United States
(12) Patent Application Publication
(10) Pub. No.: US 2007/0052114 A1
(43) Pub. Date: Mar. 8, 2007

(54) Alignment checking structure and process using thereof

(76) Inventors: Shih-Chieh Huang, Hsinchu City (TW); Chang-Ming Liu, Hsinchu City (TW); Bob Lee, Jhudong Township (TW)

Correspondence Address: J C PATENTS, INC., 4 VENTURE, SUITE 250, IRVINE, CA, 92618, US

(21) Appl. No.: 11/221,486

(22) Filed: Sep. 7, 2005

(51) Int. Cl. H01L 23/544

(52) U.S. Cl. 257/797

(57) ABSTRACT

The invention provides an alignment checking structure with a checkered pattern comprising a plurality of metal squares and a plurality of non-metal squares that are arranged in alternation, in a first direction and a second direction, and the first direction is perpendicular to the second direction

### BACKGROUND OF THE INVENTION

1. Field of Invention

The present invention relates to an alignment checking structure. More particularly, the present invention relates to an alignment checking structure and a process for evaluating the alignment with the alignment checking structure.

2. Description of Related Art

As integration of the semiconductor device increases, dimensions of the device decrease to even smaller than the wavelength of deep ultra-violate (UV) light. Photolithography technology therefore becomes a challenge for semiconductor manufacturers, since alignment accuracy and pattern fidelity in photolithography need to be increased accordingly.

For obtaining satisfactory alignment accuracy and pattern fidelity, appropriate alignment marks are required for controlling the alignment parameters of a pattern transferring system, such as a stepper machine. In the conventional exposure process, the alignment marks corresponding to the photomask are formed on the chips, in order to form a scattering site or a diffraction edge. The alignment marks can be categorized as zero marks and floating non-zero marks, or metal alignment marks. As the alignment light beam irradiates onto the chip, the diffraction pattern resulted from the alignment marks will be reflected to the alignment sensor, or the First Order Diffraction Interferometer Alignment System, so as to achieve the alignment.

Laser-based trimming has been widely applied in thin film semiconductor and silicon manufacturing for trimming circuits or blowing fuses. The technical advantages of laser trimming include higher resolution, more circuits in a fixed space and boosted functionality. However, beyond the advantages it offering, there is no efficient alignment protocol for controlling the alignment shift of the laser-trimming system. In order to check whether the laser-trimming system is precisely aligned or shifted, functional fuses on the chips are used as alignment targets and are mostly sacrificed for the alignment purposes. Furthermore, even when the alignment shift is identified, no prompt or direct measurement tools are available to feedback the shift value and the shift direction to the laser-trimming system. Therefore, it is difficult to evaluate or compare the accuracy or precision of the alignment for laser trimming between different batches of wafers or various processing platforms.

### SUMMARY OF THE INVENTION

The present invention provides an alignment checking structure applicable for laser trimming technology. The alignment checking structure can be integrated with the alignment marks and used for evaluating the alignment situation and verifying the values of the alignment shifts.

It is therefore an objective of the present invention to provide an alignment checking structure that can be used to determine the alignment errors and offset the alignment if necessary.

It is another objective of the present invention to provide a process for evaluating the alignment shifts of laser trimming with an alignment checking structure, for the analysis and control the parameters of the laser trimming system either in real time or for the future examination.

In accordance with the foregoing and other objectives of the present invention, an alignment checking structure applicable for laser trimming technology is provided. The alignment checking structure has a checkered pattern comprising a plurality of metal squares and a plurality of non-metal squares that are arranged in alternation, in a first direction and a second direction, wherein the first direction is perpendicular to the second direction.

In accordance with the foregoing and other objectives of the present invention, a process for evaluating alignment shifts of laser trimming with an alignment checking structure is provided. The process comprises providing a wafer having an alignment checking structure with a checkered pattern comprising a plurality of metal squares and a plurality of non-metal squares that are arranged in alternation, in a first direction and a second direction, while the first direction is perpendicular to the second direction; assigning a metal square in a substantially central region of the checkered pattern as a target square and a center of the target square as a target center for laser trimming; performing the laser trimming process to the alignment checking structure, so that a laser beam strikes a trimming spot of the alignment checking structure; and measuring a distance from the target center of the target square to a center of the trimming spot in the first direction and the second direction, so as to obtain the alignment shift.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic top view of the alignment checking structure according to one preferred embodiment of this invention.

FIG. 2 shows a process for evaluating the alignment shift of laser trimming with the alignment checking structure according to one preferred embodiment of this invention.

FIG. 3 is a schematic view of the arrangement of the alignment checking structure on the wafer according to one preferred embodiment of this invention.

FIG. 4 is a schematic cross-sectional view of the process for forming the alignment checking structure on the wafer according to one preferred embodiment of this invention.

### DESCRIPTION OF THE PREFERRED EMBODIMENTS

The present invention provides an alignment checking structure applicable for laser trimming technology. According to the following preferred embodiment of this invention, the arrangement of this alignment checking structure is similar to a checker board, and is called as the alignment precision checker (APC) structure in the following paragraphs. However, the design of the alignment checking structure provided by the present invention is not limited to only checkered patterns, but can be adjusted according to the layout requirements.

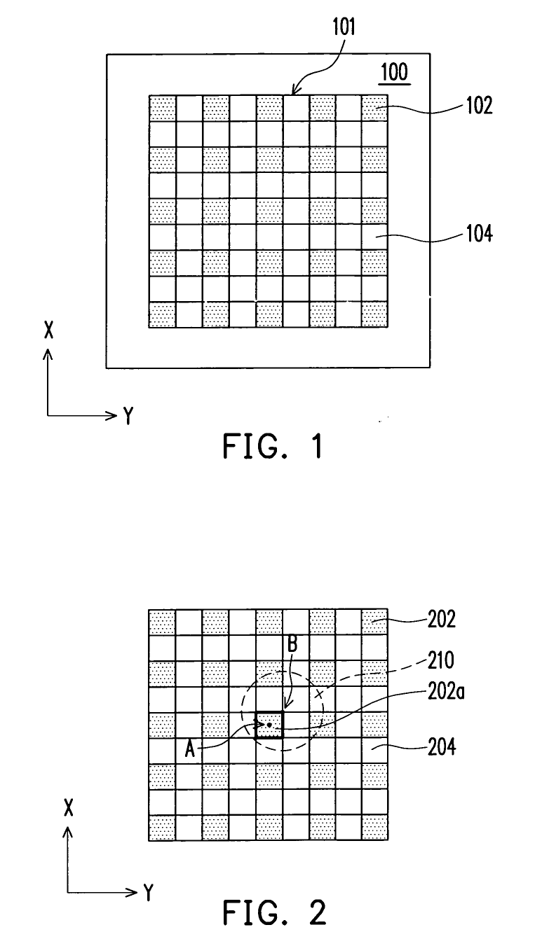

FIG. 1 is a schematic top view of the alignment checking structure according to one preferred embodiment of this invention. As shown in FIG. 1, the alignment checking structure 100 with a checkered pattern 101, includes metal squares 102 (in shades) and non-metal squares 104 arranged in alternation, in both the directions of the columns (X-axis) and the rows (Y-axis). The checkered pattern 101 can be designed to include 9 columns and 9 rows (that is, totally 81 squares including metal squares 102 and non-metal squares 104), as shown in FIG. 1. This checkered pattern can be regarded as a two-axial coordination system for easy evaluation of the alignment shifts. Taking 1 micron×1 micron squares as an example, by counting the squares of the checkered pattern, the alignment shift can be simply calculated. The size or the number of the squares can be adjusted according to the required precision of the alignment or the layout of the chip.

FIG. 2 is a graph illustrating how to evaluate the alignment shift of laser trimming with the alignment checking structure according to one preferred embodiment of this invention. Referring to FIG. 2, the central metal square 202a (marked in bold line) is assigned as the target square for laser trimming, and the center A of the central metal square 202a is regarded as the target center. During the laser trimming process, a trimming spot 210 is present, representing the trimmed region by the laser, and the center B of the trimming spot 210 is regarded as the location of the trimmed region by the laser. Because one square can be considered as a 1 μm length unit herein, the alignment shift is easily estimated by counting the distance from the target center A of the central metal square 202a to the trimming spot center B, in both the X-direction and the Y-direction. From FIG. 2, the alignment shift is calculated as 0.5 μm in X-axis and 0.5 μm in Y-axis. By doing so, the alignment shift or errors can be readily converted into numbers and values for comparison and analysis, so that the deviation of the alignment situation can be scaled.

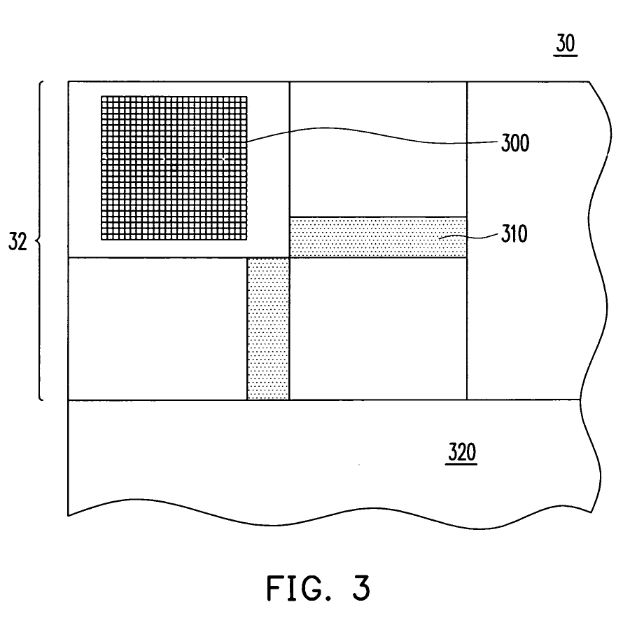

In order to save the space of the wafer, the alignment marks are usually arranged in the scribe-line regions of the wafer. FIG. 3 is a schematic view of the arrangement of the alignment checking structure on the wafer according to one preferred embodiment of this invention. Referring to FIG. 3, the alignment checking structure 300 is arranged to be close with the L-shape alignment marks 310 in the scribe-line regions 32 of the wafer 30. Commonly, the alignment checking structure 300 can be arranged at the corners of the chip 320 or in the scribe-line regions 32 of the wafer 30, so that no extra wafer area needs to be preserved for the alignment checking structure 300. However, the alignment checking structure of this invention is not limited to be arranged within the scribe-line regions, and any suitable location within the chip, region can be considered. As shown in FIG. 3, the alignment checking structure 300 is arranged beside the alignment marks 310 with a space there between. In this case, the laser trimming system (not shown) can try to locate the alignment marks 310 first and perform laser trimming to the alignment checking structure 300 for the evaluation of the alignment.

In general, the alignment checking structure of this invention requires no more than an area of 25 μm×25 μm to reasonably evaluate the alignment shifts. Still, a larger or smaller design of the alignment checking structure is encompassed within the scope of the present invention.

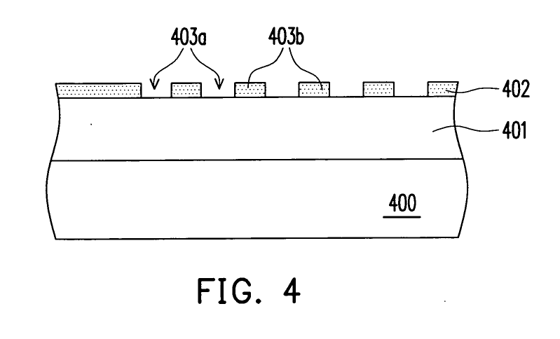

The alignment checking structure of the present invention can be obtained by patterning a metal layer with the desired pattern at the same time as patterning the fuse layer of the semiconductor device on the chip. FIG. 4 is a schematic cross-sectional view of the process for forming the alignment checking structure on the wafer according to one preferred embodiment of this invention. Referring to FIG. 4, a substrate or wafer 400 having at least a component (not shown) and an insulating film 401 over the substrate 400 are provided. After forming a metal layer 402 over the substrate 400, the metal layer 402 is patterned. Through patterning the metal layer 402, non-metal squares 403a are formed by removing the metal at the corresponding locations while the remained metal forms the metal squares 403b at the corresponding locations. That is, the non-metal squares are in fact openings beside the metal squares. However, the non-metal squares can be formed by further filling an insulating material into the openings. The material of the metal square of the alignment checking structure can be copper or aluminum or the alloys thereof, for example. Therefore, the fabrication of the alignment checking structure can make use of the currently existing fabrication processes.

Accordingly, the present invention provides an alignment checking structure that can be used to determine the alignment errors. The alignment errors or shifts can be converted into numbers and values and the alignment shift values are later used to offset the alignment in real time or for the next batch, if necessary. Alternatively, through the use of the alignment checking structure, the obtained alignment shift values can be used to analyze the distribution of the alignment shifts for laser trimming toward different locations in the same wafer or between different batches of wafers.

The alignment checking structure needs can make use of the blank space (such as, the scribe-line regions) of the wafer and be integrated with the alignment marks, so that no extra area needs to be preserved for the alignment checking structure. Furthermore, by using the alignment checking structure, there is no need to sacrifice functional fuses on the chips for testing. In addition, because the fabrication process of the alignment checking structure is compatible with the currently existing processes, no extra costs are added.

Since the alignment accuracy directly affects the reliability and the yields of the products, the alignment checking structure of this invention can help to improve the alignment accuracy and enhance device performances by using the alignment checking structure as a tool to locate the alignment positions and evaluate the alignment shifts.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An alignment checking structure applicable for laser trimming technology, arranged on a wafer, wherein the alignment checking structure has a checkered pattern comprising a plurality of metal squares and a plurality of non-metal squares that are alternatively arranged in a first direction and a second direction, wherein the first direction is perpendicular to the second direction.

2. The structure as claimed in claim 1, wherein a material of the metal square comprises copper.

3. The structure as claimed in claim 1, wherein a material of the metal square comprises aluminum.

4. The structure as claimed in claim 1, wherein a size of the metal square is about 1 μm×1 μm.

5. The structure as claimed in claim 4, wherein a size of the non-metal square is about 1 μm×1 μm.

6. The structure as claimed in claim 1, wherein the metal square and the non-metal square have the same size.

7. The structure as claimed in claim 1, wherein the alignment checking structure is arranged beside alignment marks on scribe-lines of the wafer.

8. The structure as claimed in claim 1, wherein the alignment checking structure is arranged at a corner of a chip of the wafer.

9. A process for evaluating an alignment shift for a laser trimming process, comprising:
providing a wafer having an alignment checking structure with a checkered pattern comprising a plurality of metal squares and a plurality of non-metal squares that are alternatively arranged in a first direction and a second direction, wherein the first direction is perpendicular to the second direction;
assigning a metal square in a substantially central region of the checkered pattern as a target square and a center of the target square as a target center for laser trimming;
performing the laser trimming process to the alignment checking structure, so that a laser beam strikes a trimming spot of the alignment checking structure; and
measuring a distance from the target center of the target square to a center of the trimming spot in the first direction and the second direction, so as to obtain the alignment shift.

10. The process as claimed in claim 9, wherein the alignment checking structure is arranged beside alignment marks on scribe-lines of the wafer.

11. The process as claimed in claim 10, further comprising locating the alignment marks before the step of performing the laser trimming process to the alignment checking structure.

12. The process as claimed in claim 9, wherein the alignment checking structure is arranged at a corner of a chip of the wafer.

13. The process as claimed in claim 9, wherein the metal square and the non-metal square have the same size.
